(19) United States
(12) Patent Application Publication
(10) Pub. No.: US 2025/0113527 A1
(43) Pub. Date: Apr. 3, 2025

(54) SEMICONDUCTOR STRUCTURE

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/825,428

(22) Filed: Sep. 5, 2024

(30) Foreign Application Priority Data
Sep. 28, 2023 (CN) 202322662719.9

(51) Int. Cl. H01L 29/778; H01L 29/06; H01L 29/20

(52) U.S. Cl. CPC H10D 30/4755; H10D 62/107; H10D 62/125; H10D 62/8503

(57) ABSTRACT

A semiconductor structure includes: a substrate; a heterojunction structure, including a channel layer and a barrier layer which are disposed on the substrate in sequence, and being divided into a gate region, a source region and a drain region; a gate located in the gate region, a source located in the source region and a drain located in the drain region; a first groove, located in the source region, and located on a side of the heterojunction structure close to the source; and a first p-type semiconductor layer which fills the first groove, where the source is connected to the barrier layer and the first p-type semiconductor layer simultaneously.

### CROSS-REFERENCE TO RELATED APPLICATIONS

The present application claims priority to Chinese Patent Application No. 202322662719.9, filed on Sep. 28, 2023, the disclosure of which is hereby incorporated by reference in its entirety.

### TECHNICAL FIELD

The present disclosure relates to the field of semiconductor technologies, and in particular, to a semiconductor structure.

### BACKGROUND

As a representative of the third generation semiconductor, GaN has many advantages, such as a large band gap, a high saturation drift velocity, a high critical breakdown field strength, a high thermal conductivity and the like, especially, when a GaN heterostructure is not doped, high-concentration two-dimensional electron gas may be generated through a strong spontaneous polarization effect, and due to the excellent performance, it is widely applied to fields of power electronics and radio frequency microwave and the like.

The reliability problem represented by current collapse is one of the most serious problems for a GaN-based power switching device finally to be put into practical use. The current collapse causes a dynamic resistance of the device to be reduced, which increases a dynamic response time of the power switching device, so that a reliability of the device is greatly reduced. Traps on a surface and a barrier layer and a high-resistance GaN buffer layer are all considered as important factors for causing the current collapse phenomenon, among which the current collapse caused by the high-resistance GaN buffer layer under an action of a drain end stress is one of the focuses of people's research. A buffer layer of a Si-based GaN power switching device is often doped with C, resulting in a PN junction being formed between the channel and the buffer layer. When the device is turned off, the PN junction is depleted at a high drain voltage. After the device is turned on, since it takes some time for a hole in the buffer layer to recover, and channel electrons cannot be recovered immediately, resulting in a phenomenon of the current collapse.

### SUMMARY

To solve the above-mentioned technical problem, the present disclosure is proposed. A embodiment of the present disclosure provides a semiconductor structure, including: a substrate; a heterojunction structure, including a channel layer and a barrier layer which are disposed on the substrate in sequence, the heterojunction structure including a gate region, and a source region and a drain region which are located on two sides of the gate region respectively, a gate located in the gate region, a source located in the source region and a drain located in the drain region; a first groove, located in the source region, the first groove being located on a side of the heterojunction structure close to the source; and a first p-type semiconductor layer which fills the first groove, where the source is connected to the barrier layer and the first p-type semiconductor layer simultaneously.

As an optional embodiment, the first p-type semiconductor layer is prepared in the first groove by means of secondary epitaxy.

As an optional embodiment, there are a plurality of the first grooves, the plurality of the first grooves are arranged at intervals along a first direction, and the plurality of the first grooves extend along a second direction, where the first direction and the second direction are perpendicular to each other, the first direction and the second direction are parallel to the substrate, and the second direction is a direction in which the source points to the drain.

As an optional embodiment, in the second direction, a width of an opening of the first groove is constant, or gradually decreases, or first increases and then decreases.

As an optional embodiment, there are a plurality of the first grooves, the plurality of the first grooves are distributed in an array, and a shape of a cross section of the first groove is any one of a triangle, a square, a strip, a polygon, a circle or an ellipse, and the cross section is a plane parallel to the substrate.

As an optional embodiment, in a third direction, a width of an opening of the first groove is constant, or gradually decreases, or gradually increases. The third direction is a direction in which the heterojunction structure points to the substrate.

As an optional embodiment, the semiconductor structure further includes a buffer layer located between the substrate and the channel layer. A bottom of the first groove is located on a surface of a side of the buffer layer away from the substrate; or, the first groove partially penetrates the buffer layer, and a bottom of the first groove is located in the buffer layer; or, the first groove penetrates through the buffer layer.

As an optional embodiment, the semiconductor structure further includes a dielectric layer which covers a side of the barrier layer away from the substrate, where the dielectric layer is located between the barrier layer and the gate.

As an optional embodiment, the substrate is a semi-insulating substrate.

As an optional embodiment, a second groove is provided on a surface of a side of the substrate close to the channel layer, the channel layer and the barrier layer are conformally provided on the substrate in sequence, a third groove corresponding to the second groove is formed on a surface of a side of the barrier layer away from the substrate, and the gate is disposed in the third groove.

As an optional embodiment, the semiconductor structure further includes a second p-type semiconductor layer which is located in the gate region, where the second p-type semiconductor layer is located in the third groove and covers an inner wall of the third groove, and the gate is located on a side of the second p-type semiconductor layer away from the substrate.

### BRIEF DESCRIPTION OF THE DRAWINGS

The above-mentioned and other objects, features and advantages of the present disclosure will become more apparent by describing embodiments of the present disclosure in more detail with reference to the drawings. The drawings are used for providing a further understanding of the embodiments of the present disclosure and constitute a portion of the specification, which are used for explaining the present disclosure together with the embodiments of the present disclosure, and do not constitute a limitation of the present disclosure. In the drawings, a same reference numeral generally represents a same component or step.

FIG. 1 is a schematic structural diagram of a semiconductor structure according to Embodiment 1 of the present disclosure.

FIG. 2 is a top view of a semiconductor structure according to Embodiment 2 of the present disclosure.

FIG. 3a to FIG. 3c are top views of the semiconductor structure omitting a source according to Embodiment 2 of the present disclosure.

FIG. 4a to FIG. 4d are top views of a semiconductor structure omitting a source according to Embodiment 3 of the present disclosure.

FIG. 5a and FIG. 5b are schematic structural diagrams of a semiconductor structure according to Embodiment 4 of the present disclosure.

FIG. 6 is a schematic structural diagram of a semiconductor structure according to Embodiment 5 of the present disclosure.

FIG. 7 is a schematic structural diagram of a semiconductor structure according to Embodiment 6 of the present disclosure.

FIG. 8 is a schematic structural diagram of a semiconductor structure according to Embodiment 7 of the present disclosure.

FIG. 9 is a schematic structural diagram of another semiconductor structure according to the Embodiment 5 of the present disclosure.

FIG. 10 is a schematic structural diagram of a semiconductor structure according to Embodiment 8 of the present disclosure.

FIG. 11 is a schematic structural diagram of another semiconductor structure according to the Embodiment 8 of the present disclosure.

FIG. 12 is a schematic structural diagram of another semiconductor structure according to the Embodiment 8 of the present disclosure.

### DETAILED DESCRIPTION OF THE EMBODIMENTS

The technical solutions in the embodiments of the present disclosure will be clearly and completely described below with reference to the drawings in the embodiments of the present disclosure. Apparently, the described embodiments are merely a portion but not all of the embodiments of the present disclosure. All other embodiments obtained by a person having ordinary skill in the art based on the embodiments of the present disclosure without creative efforts shall fall within the protection scope of the present disclosure.

### Embodiment 1

FIG. 1 is a schematic structural diagram of a semiconductor structure according to Embodiment 1 of the present disclosure. Referring to FIG. 1, the semiconductor structure provided in the Embodiment 1 includes a substrate 1, a heterojunction structure 5 formed on the substrate 1, a gate 53, a source 51 and a drain 52 which are disposed on a side of the heterojunction structure 5 far away from the substrate 1, a first groove 6 and a first p-type semiconductor layer 61 which fills the first groove 6. The heterojunction structure 5 includes a channel layer 3 and a barrier layer 4 which are disposed on the substrate 1 in sequence. The heterojunction structure 5 includes a gate region 5C, and a source region 5A and a drain region 5B which are located on two sides of the gate region 5C, respectively. The gate 53 is located in the gate region 5C, the source 51 is located in the source region 5A, and the drain 52 is located in the drain region 5B. The first groove 6 is located in the source region 5A, and is located on a side of the heterojunction structure 5 close to the source 51. The source 51 is connected to the barrier layer 4 and the first p-type semiconductor layer 61 simultaneously.

In the semiconductor structure provided in the present embodiment, the first groove 6 is provided in the heterojunction structure 5, and the first p-type semiconductor layer 61 is prepared in the first groove 6. The source 51 is connected to the barrier layer 4 and the first p-type semiconductor layer 61 simultaneously, which provides enough injection of holes, so that a recovery time of a depletion layer is shortened, thus a recovery time of a channel current is shortened, and thus current collapse is reduced. In addition, a manufacturing difficulty of the semiconductor structure provided in the present embodiment is low, so that a preparing time is saved, and thus a preparing cost is effectively reduced.

Optionally, the first p-type semiconductor layer 61 is prepared in the first groove 6 by means of secondary epitaxy. In the present embodiment, the first groove 6 at least penetrates through the heterojunction structure 5, that is, the first groove 6 at least penetrates through the barrier layer 4 and the channel layer 3, so that the first p-type semiconductor layer 61 is connected to the substrate 1.

In the present embodiment, the substrate 1 is a semi-insulating substrate, and a material of the substrate 1 may be any one of Si, SiC, Al₂O₃, AlN, GaN or ceramic.

The heterojunction structure 5 is a GaN-based material, optionally, a material of the channel layer 3 is GaN, and a material of the barrier layer 4 is AlGaN.

A material of the first p-type semiconductor layer 61 is p-type GaN or p-type AlGaN and the like.

### Embodiment 2

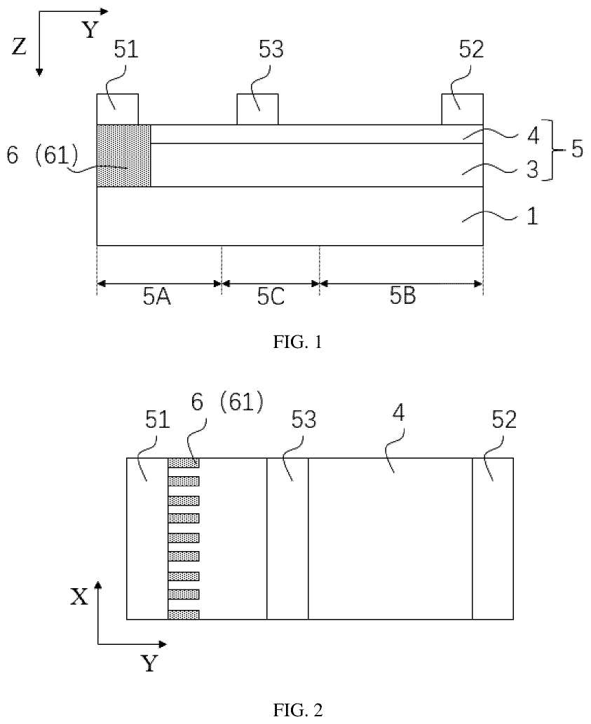

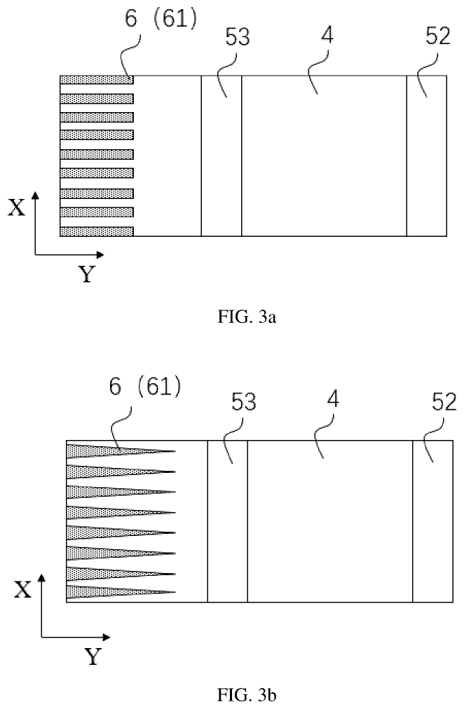

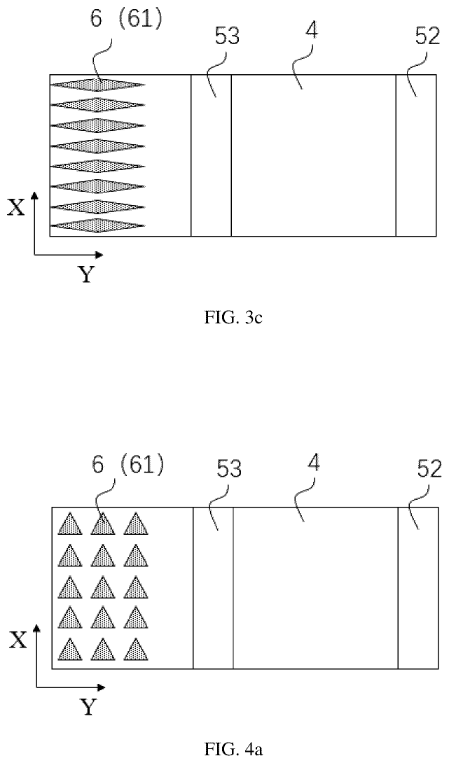

The content of the Embodiment 2 is substantially the same as that of the Embodiment 1, and differences are only as shown in FIG. 2 and FIG. 3a to FIG. 3c. FIG. 2 is a top view of a semiconductor structure according to Embodiment 2 of the present disclosure, FIG. 3a to FIG. 3c are top views of a semiconductor structure omitting a source 51 according to Embodiment 2 of the present disclosure. There are a plurality of the first grooves 6, the plurality of the first grooves 6 are distributed at intervals along a first direction X, and the plurality of the first grooves 6 extend along a second direction Y. The first direction X and the second direction Y are perpendicular to each other, the first direction X and the second direction Y are parallel to the substrate 1, and the second direction Y is a direction in which the source 51 points to the drain 52.

In the present embodiment, optionally, along the second direction Y, a width of an opening of the first groove is constant, or gradually decreases, or first increases and then decreases. As shown in FIG. 3a, along the second direction Y, the width of the opening of the first groove is constant. As shown in FIG. 3b, along the second direction Y, the width of the opening of the first groove gradually decreases. As shown in FIG. 3c, along the second direction Y, the width of the opening of the first groove first increases and then decreases. A specific width of the opening of the first groove 6 may be selected according to an actual situation, which is not limited in the present embodiment herein.

### Embodiment 3

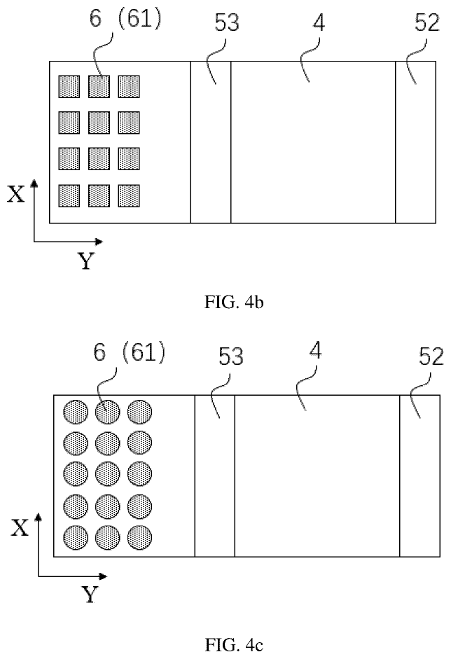

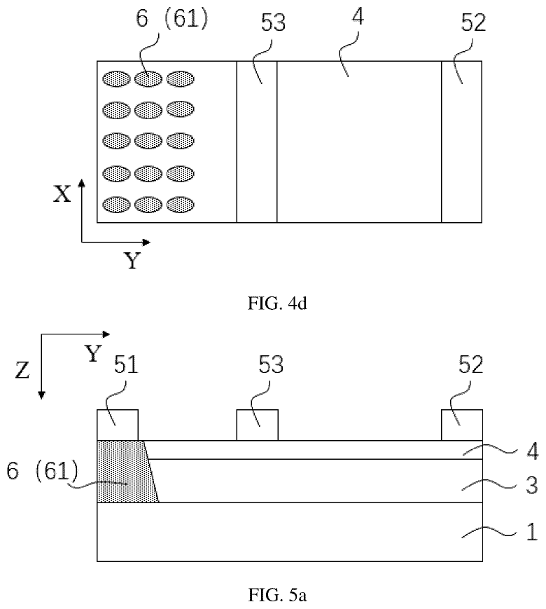

The content of Embodiment 3 is substantially the same as that of the Embodiment 1 or the Embodiment 2, and differences are only as shown in FIG. 4a to FIG. 4d. FIG. 4a to FIG. 4d are top views of a semiconductor structure omitting a source 51 according to Embodiment 3 of the present disclosure. There are a plurality of the first grooves 6, and the plurality of the first groove s 6 are distributed in an array. A shape of a cross section of the first groove 6 is any one of a triangle, a square, a strip, a polygon, a circle or an ellipse, and the cross section is a plane parallel to the substrate 1.

### Embodiment 4

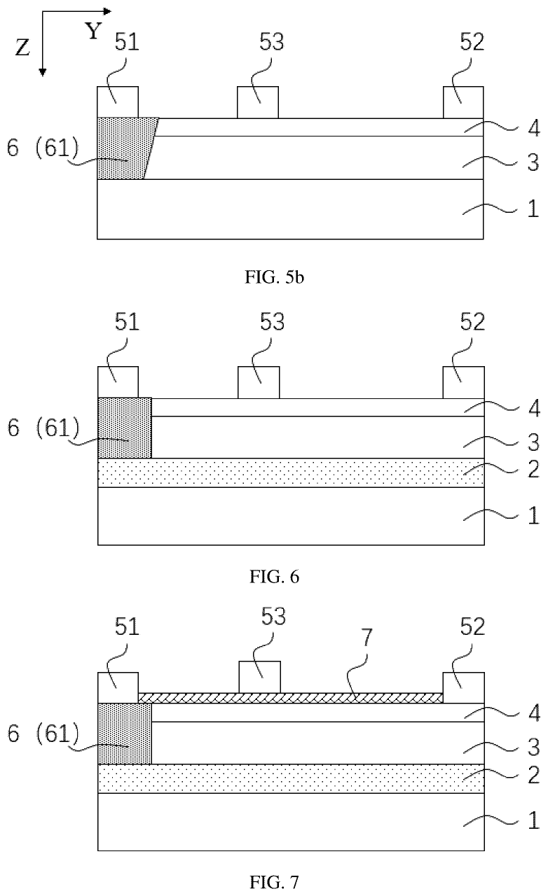

The content of the Embodiment 4 is substantially the same as that of any one of the Embodiments 1 to 3, differences are only as shown in FIG. 5a and FIG. 5b. FIG. 5a and FIG. 5b are schematic structural diagrams of a semiconductor structure according to the Embodiment 4 of the present disclosure. In a third direction Z, the width of the opening of the first groove 6 is constant, or gradually decreases, or gradually increases. The third direction Z is a direction in which the heterojunction structure 5 points to the substrate 1.

As shown in FIG. 5a, along the third direction Z, the width of the opening of the first groove 6 gradually increases. As shown in FIG. 5b, along the third direction Z, the width of the opening of the first groove 6 gradually decreases.

### Embodiment 5

The content of the Embodiment 5 is substantially the same as that of any one of the Embodiments 1 to 4, the differences are only as shown in FIG. 6 or FIG. 9. FIG. 6 is a schematic structural diagram of a semiconductor structure according to Embodiment 5 of the present disclosure. FIG. 9 is a schematic structural diagram of another semiconductor structure according to the Embodiment 5 of the present disclosure. In the semiconductor structure provided in the Embodiment 5, the semiconductor structure further includes a buffer layer 2 provided between the substrate 1 and the heterojunction structure 5. That is, the buffer layer 2 is disposed between the substrate 1 and the channel layer 3. A bottom of the first groove 6 is located on a surface of a side of the buffer layer 2 away from the substrate 1. In other embodiments, optionally, the first groove 6 may partially penetrate the buffer layer 2, and the bottom of the first groove 6 is located in the buffer layer 2; or, the first groove 6 may fully penetrate through the buffer layer 2, and the bottom of the first groove 6 is connected to the substrate 1.

Optionally, a material of the buffer layer 2 is any one of AlN, AlGaN, GaN or the like.

### Embodiment 6

The content of the Embodiment 6 is substantially the same as that of any one of the Embodiments 1 to 5, differences are only as shown in FIG. 7. FIG. 7 is a schematic structural diagram of a semiconductor structure according to Embodiment 6 of the present disclosure. The semiconductor structure provided in the Embodiment 6 further includes a dielectric layer 7. The dielectric layer 7 covers a side of the barrier layer 4 away from the substrate 1, and the dielectric layer 7 is located between the barrier layer 4 and the gate 53.

The dielectric layer 7 is any one or any combination of SiN, SiCN, SiO₂, SiAlN, Al₂O₃, AlON, SiON, HfO₂ and HfAlO.

### Embodiment 7

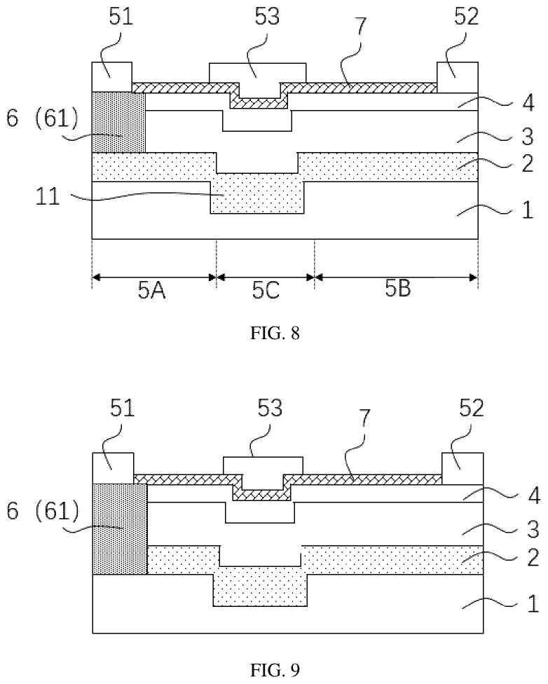

The content of the Embodiment 7 is substantially the same as that of any one of the Embodiments 1 to 6, differences are only as shown in FIG. 8 and FIG. 9. FIG. 8 is a schematic structural diagram of a semiconductor structure according to Embodiment 7 of the present disclosure. A second groove 11 is provided on a surface of a side of the substrate 1 close to the channel layer 3. The second groove 11 corresponds to the gate region 5C of the heterojunction structure 5. The channel layer 3 and the barrier layer 4 are conformally provided on the substrate 1 in sequence, that is, a third groove corresponding to the second groove 11 is formed on the surface of a side of the barrier layer 4 away from the substrate 1, and the gate 53 is disposed in the third groove. Optionally, the gate 53 is a T-shaped gate.

The semiconductor structure provided in the present embodiment does not need to etch the barrier layer 4 to prepare an enhanced device, thereby avoiding device performance degradation caused by a damage of an active region, for example, a low current density or a current collapse effect, or the like. In addition, the semiconductor structure provided in the Embodiment 7 also does not need to introduce Mg atoms to realize preparing p-type nitride, thereby avoiding contamination to a metalorganic chemical vapor deposition (MOCVD) chamber or a molecular beam epitaxy (MBE) chamber.

### Embodiment 8

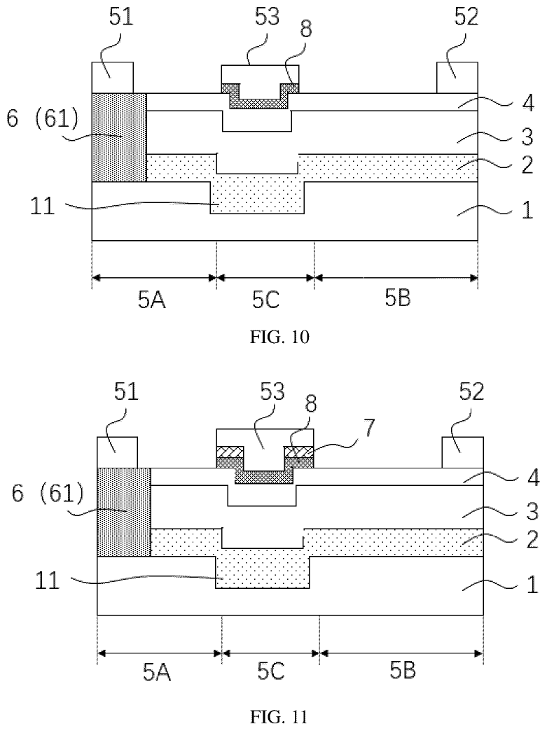

The content of the Embodiment 8 is substantially the same as that of the Embodiment 7, differences are only as shown in FIG. 10. FIG. 10 is a schematic structural diagram of a semiconductor structure according to Embodiment 8 of the present disclosure. The semiconductor structure provided in the Embodiment 8 further includes a second p-type semiconductor layer 8 which is located in the gate region 5C. The second p-type semiconductor layer 8 is disposed on a side of the barrier layer 4 away from the substrate 1. The second p-type semiconductor layer 8 is located in the third groove and covers an inner wall of the third groove, and the gate 53 is located on a side of the second p-type semiconductor layer 8 away from the substrate 1.

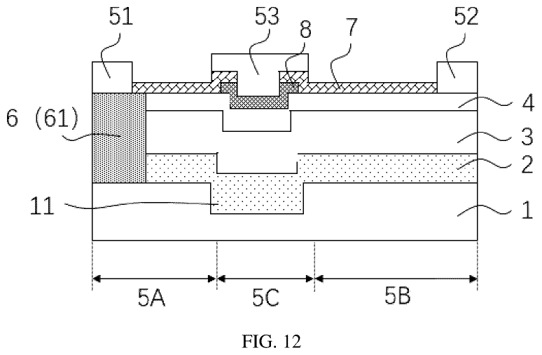

Optionally, referring to FIG. 11 and FIG. 12. FIG. 11 is a schematic structural diagram of another semiconductor structure according to the Embodiment 8 of the present disclosure. A dielectric layer 7 may be provided between the second p-type semiconductor layer 8 and the gate 53. The dielectric layer 7 is conformally disposed on a surface of the side of the second p-type semiconductor layer 8 away from the substrate 1. The dielectric layer 7 is provided with an opening, and the gate 53 is connected to the second p-type semiconductor layer 8 through the opening of the dielectric layer 7. Referring to FIG. 12, FIG. 12 is a schematic structural diagram of another semiconductor structure according to the Embodiment 8 of the present disclosure. The difference between the FIG. 12 and FIG. 11 is only that, the dielectric layer 7 may further cover a surface of a side of the barrier layer 4 away from the substrate 1 and a sidewall of the second P-type semiconductor layer 8.

The arrangement of the second p-type semiconductor layer 8 effectively improves a controllability of the gate 53, so that leakage current in the gate region is avoided, and the dielectric layer 7reduces a possibility that the breakdown is caused by an excessively high voltage of the gate region, and serves as a protective layer to protect the device structure, and thus reliability of the device is improved.

In the semiconductor structure provided by the present disclosure, the first groove 6 is provided in the heterojunction structure 5, the first p-type semiconductor layer 61 is prepared in the first groove 6, and the source 51 is connected to the barrier layer 4 and the first p-type semiconductor layer 61 simultaneously. Therefore, sufficient injection of holes is provided, so that the recovery time of the depletion layer is shortened, thus the recovery time of the channel current is shortened, and thus the possibility of the current collapse is reduced. In addition, the preparation difficulty of the semiconductor structure of the present disclosure is low, so that the preparation cost is effectively reduced.

The basic principle of the present disclosure is described above with reference to specific embodiments, but it should be noted that the advantages, effects and the like mentioned in the present disclosure are merely illustrations, not limitations, and these advantages, effects, etc. cannot be considered as necessary for each embodiment of the present disclosure. In addition, the specific details disclosed above are only for the purpose of illustration and for ease of understanding, but not limitations, and the foregoing details are not intended to limit the present disclosure to be implemented by adopting the specific details above-mentioned.

The block diagrams of devices, apparatuses, devices, and systems involved in the present disclosure are merely illustrative examples and are not intended to require or imply that they must be connected, arranged and configured in the manner shown in the block diagrams. As a person skilled in the art will recognize, these devices, apparatuses, devices, systems may be connected, arranged, configured in any manner. The words such as “comprise”, “include”, “have” and the like are open words, and refer to “include but not limited to” and may be used interchangeably. The words “or” and “and” as used herein refer to the word “and/or” and may be used interchangeably, unless the context clearly dictates otherwise. The term “such as” used herein refers to the phrase “such as, but not limited to” and may be used interchangeably therewith.

It should also be noted that, in the apparatus, device, and method of the present disclosure, each component or each step may be decomposed and/or recombined. These decomposition and/or recombination should be considered as equivalent solutions of the present disclosure.

The above description of the disclosed aspects is provided to enable any person skilled in the art to make or use the present disclosure. Various modifications to these aspects are obvious to a person skilled in the art, and the general principles defined herein may be applied to other aspects without departing from the scope of the disclosure. Thus, the present disclosure is not intended to be limited to the aspects shown herein but is to be accorded the widest scope consistent with the principles and novel features disclosed herein. The above description has been presented for purposes of illustration and description. Moreover, this description is not intended to limit the embodiments of the present disclosure to the forms disclosed herein. Although various example aspects and embodiments have been discussed above, a person skilled in the art will recognize certain variations, modifications, changes, additions, and sub-combinations thereof.

What is claimed is:

1. A semiconductor structure, comprising:
a substrate;
a heterojunction structure, comprising a channel layer and a barrier layer which are disposed on the substrate in sequence, the heterojunction structure comprising a gate region, and a source region and a drain region which are located on two sides of the gate region respectively;
a gate located in the gate region, a source located in the source region and a drain located in the drain region,
a first groove, located in the source region, the first groove being located on a side of the heterojunction structure close to the source; and
a first p-type semiconductor layer which fills the first groove, wherein the source is connected to the barrier layer and the first p-type semiconductor layer simultaneously.

2. The semiconductor structure according to claim 1, wherein the first p-type semiconductor layer is prepared in the first groove by means of secondary epitaxy.

3. The semiconductor structure according to claim 1, wherein there are a plurality of the first grooves, the plurality of the first grooves are arranged at intervals along a first direction, and the plurality of the first grooves extend along a second direction;
the first direction and the second direction are perpendicular to each other, the first direction and the second direction are parallel to the substrate, and the second direction is a direction in which the source points to the drain.

4. The semiconductor structure according to claim 3, wherein along the second direction, a width of an opening of the first groove is constant, or gradually decreases, or firstly increases and then decreases.

5. The semiconductor structure according to claim 1, wherein there are a plurality of the first grooves, and the plurality of the first grooves are distributed in an array.

6. The semiconductor structure according to claim 5, wherein a shape of a cross section of the first groove is any one of a triangle, a square, a strip, a polygon, a circle or an ellipse, and the cross section is a plane parallel to the substrate.

7. The semiconductor structure according to claim 1, wherein in a third direction, a width of an opening of the first groove is constant, or gradually decreases, or gradually increases, the third direction is a direction in which the heterojunction structure points to the substrate.

8. The semiconductor structure according to claim 1, further comprising:
a buffer layer, disposed between the substrate and the channel layer, wherein
a bottom of the first groove is located on a surface of a side of the buffer layer away from the substrate.

9. The semiconductor structure according to claim 1, further comprising:
a buffer layer, disposed between the substrate and the channel layer, wherein
the first groove partially penetrates the buffer layer, and a bottom of the first groove is located in the buffer layer.

10. The semiconductor structure according to claim 1, further comprising:
a buffer layer, disposed between the substrate and the channel layer, wherein the first groove penetrates through the buffer layer.

11. The semiconductor structure according to claim 1, further comprising:
a dielectric layer, which covers a side of the barrier layer away from the substrate, wherein the dielectric layer is located between the barrier layer and the gate.

12. The semiconductor structure according to claim 11, wherein the dielectric layer is any one or any combination of SiN, SiCN, SiO₂, SiAlN, Al₂O₃, AlON, SiON, HfO₂ and HAlO.

13. The semiconductor structure according to claim 1, wherein the substrate is a semi-insulating substrate.

14. The semiconductor structure according to claim 13, wherein the gate is a T-shaped gate.

15. The semiconductor structure according to claim 1, wherein a second groove is provided on a surface of a side of the substrate close to the channel layer, the channel layer and the barrier layer are conformally provided on the substrate in sequence, a third groove corresponding to the second groove is formed on a surface of a side of the barrier layer away from the substrate, and the gate is disposed in the third groove.

16. The semiconductor structure according to claim 15, further comprising:
a second p-type semiconductor layer which is located in the gate region, wherein the second p-type semiconductor layer is located in the third groove and covers an inner wall of the third groove, and the gate is located on a side of the second p-type semiconductor layer away from the substrate.

17. The semiconductor structure according to claim 16, wherein a dielectric layer is provided between the second p-type semiconductor layer and the gate, the dielectric layer is conformally disposed on a surface of a side of the second p-type semiconductor layer away from the substrate, the dielectric layer is provided with an opening, and the gate is connected to the second p-type semiconductor layer through the opening of the dielectric layer.

18. The semiconductor structure according to claim 17, wherein the dielectric layer covers a surface of the side of the barrier layer away from the substrate and a side wall of the second p-type semiconductor layer.

19. The semiconductor structure according to claim 1, wherein the first groove at least penetrates through the barrier layer and the channel layer, to make the first p-type semiconductor layer be connected to the substrate.

20. The semiconductor structure according to claim 1, wherein a material of the first p-type semiconductor layer is p-type GaN or p-type AlGaN.
